(19) United States
(12) Patent Application Publication
(10) Pub. No.: US 2012/0001668 A1
(43) Pub. Date: Jan. 5, 2012

(54) DIE AND A PACKAGE COMPRISING A PLURALITY OF DIES

(75) Inventors: Ignazio Antonino Urzi, Voreppe (FR); Philippe D'Audigier, Crolles (FR)

(73) Assignee: STMicroelectronics (Grenoble 2) SAS, Grenoble (FR)

(21) Appl. No.: 13/172,421

(22) Filed: Jun. 29, 2011

(30) Foreign Application Priority Data
Jul. 2, 2010 (EP) 10305728.7

(51) Int. Cl. H03L 7/00

(52) U.S. Cl. 327/142

(57) ABSTRACT

A first die includes a controller configured to select at least one task to be performed by the first die and signal circuitry configured in response to the selection of the at least one task to provide a signal to be sent to a second die for initiating performance of at least one task on the second die which corresponds to (and is to be performed in a time coordinated manner with) the at least one task on the first die. The first die has task circuitry configured to perform the task in response to generation of the signal, and the second die has task circuitry configured to perform the corresponding task in response to receipt of the signal.

### PRIORITY CLAIM

This application claims priority from European Application for Patent No. 10305728.7 filed Jul. 2, 2010, the disclosure of which is hereby incorporate by reference.

### TECHNICAL FIELD

The present invention relates to a die and a package comprising a plurality of dies.

### SUMMARY

It has been proposed by the Applicant to provide a plurality of integrated circuit dies incorporated within a single package. In such an environment, the execution of tasks in a plurality of integrated circuit dies within the single package may need to synchronized.

According to an aspect, there is provided a die comprising: a controller configured to select at least one task to be performed on said die; signal circuitry configured in response to the selection of said at least one task to provide a signal to be sent to a second die to initiate performance of said selected at least one task on said second die; and task circuitry configured in response to said signal to cause said selected at least one task to be performed.

According to an aspect, there is provided a die comprising: a controller configured to select at least one task to be performed on said die; an output configured in use to be connected to a second die; signal circuitry configured in response to the selection of said at least one task to provide a signal to said output, for initiating performance of said selected at least one task on said second die; and task circuitry configured in response to said signal to cause said selected at least one task to be performed

According to another aspect, there is provided a die comprising; a register comprising a plurality of entries, each entry corresponding to a task which is to be time coordinated with a task on a second die; a controller configured to set at least one entry of said register and to cause at least one corresponding entry in a register on a second die to be set; synchronization circuitry configured, in response to said at least one entry being set to cause a synchronization signal to be sent to said second die; and task circuitry, configured in response to said at least one entry being set to cause said task corresponding to said entry to be performed.

The synchronization circuitry may comprise a logic gate.

The controller may be configured to determine an order for a plurality of tasks to be performed.

According to another aspect, there is provided a die comprising: an input configured to receive a task selecting signal from a first die selecting at least one task to be performed on said die; an input configured to receive a task initiating signal from the first die; and task circuitry configured in response to said at least one task being selected and receipt of said task initiating signal to cause said at least one task to be performed.

According to another aspect, there is provided a die comprising: a register comprising a plurality of entries, each entry corresponding to a task which is to be time coordinated with a task on a first die; an input configured to receive a control signal, said control signal configured to set at least one entry of said register; a input configured to receive a synchronization signal from said first die; and task circuitry, configured in response to said at least one entry being set and the receipt of the synchronization signal to cause said task corresponding to said entry to be performed.

The control circuitry may comprise a logic gate.

### BRIEF DESCRIPTION OF THE DRAWINGS

Some embodiments of the present invention will now be described by way of example only to the accompanying Figures in which:

FIG. 1 shows a schematic view of two dies; and

FIG. 2 shows an example of synchronized tasks being performed in two dies.

### DETAILED DESCRIPTION OF THE DRAWINGS

In some embodiments of the present invention, a plurality of integrated circuit dies is incorporated within a single package. In the following examples, a single package having two dies is described. However, it should be appreciated that this is by way of example only and more than two dies may be provided in some embodiments of the invention.

When two or more dies are provided in a single package, it may be required to synchronize the execution of tasks in the two dies. For example, different areas of the system on chip SoC provided by the single package may require timing coordination. One example of timing coordination is synchronization. For example, two tasks on two dies need to take place at substantially the same time. For example, one or more of the following tasks may require timing coordination such as synchronization: clock recovery; clock synchronization; security task; fast inter-die mail boxes, or the like. These are only a few examples of tasks which need to be synchronized or have some other predefined timing relationship. Another example of timing coordination is where one task on one die needs to take place before or after another task on the other die. In some embodiments, the two tasks may have to be performed within a given time frame, which may be relatively small.

In some embodiments, the timing control of the tasks is provided by software as will be discussed later.

In general, known solutions to address synchronization issues tend to use a time multiplexing approach. Time multiplexing might not be suitable for addressing the requirements of a system built using a plurality of dies in a single package architecture particularly where there may be no predefined order of execution for a plurality of tasks.

Some embodiments disclosed herein may be backwardly compatible with existing hardware time multiplexing solutions. As will be discussed, the control of the order in which tasks are performed by may be provided by software. The software program can be arranged to emulate the ordering of a time multiplexing approach if required. Thus, with some embodiments, it may be possible to achieve similar results to hardware time multiplexing solutions using software in order to synchronize sequential tasks in a given order.

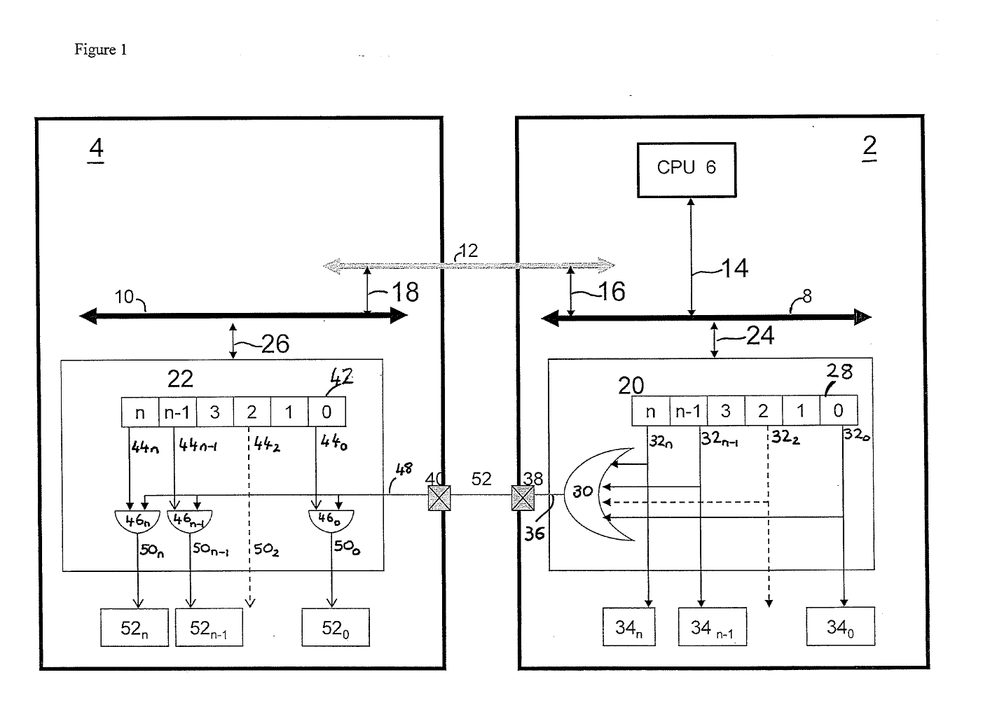

Reference is made to FIG. 1 which shows a first die 2 and a second die 4. The first die 2 is coupled to the second die 4 via an inter-die link 12 or the like. The first die 2 has a host CPU (Central Processing Unit) 6. The host CPU 6 is arranged to be coupled, via connection 14, to an interconnect bus 8 of the first die 2. A connection or other link 16 is provided between the interconnect bus 8 of the first die 2 and the inter-die link 12.

The first die 2 is provided with synchronization circuitry 20. The synchronization circuitry 20 is coupled to the interconnect bus 8 via link or connection 24. The synchronization circuitry 20 comprises a register 28 and signal circuitry. The synchronization register 28 has n+1 bits, each of the bits being associated with a particular task. In the example shown, the synchronization register 28 has bits associated with tasks 0 to n.

A respective output 32₀-32ₙ is associated with each bit of the register 28. The respective outputs 32₀-32ₙ are each provided to a respective input of an OR gate 30.

Further each of the outputs 32₀-32ₙ is provided to respective task circuitry 34₀₋ₙ. Thus, bit k is associated with task k. For example task circuitry 34ₙ₋₁ is associated with task n−1 and is associated with bit n−1 of the register 28.

The output 36 of the OR gate 30 is provided to an output pad 38 of the first die 2. The output pad 38 of the first die 2 is linked via interconnect 52 to an input pad 40 of the second die 4. It should be appreciated that in one preferred embodiment of the invention, the connection between the pads comprises a single connection such as a single wire or the like. As will be discussed later, this single link can be used to synchronize one, two or more tasks on the two dies.

The second die 4 has an interconnect bus 10 which is coupled via a connection or link 18 to the inter-die link 12. The interconnect bus 10 of the second die 4 is coupled via connection 26 to synchronization circuitry 22. The synchronization circuitry 22 on the second die 4 comprises a register 42 and signal circuitry. This register 42 has a bit corresponding to each bit in the register 28 on the first die 2. In particular, there is a 1 to 1 correspondence between the bits of the register 28 in the first die 2 and the bits in the register 42 on the second die 4. In other words, bit k of the register 28 on the first die 2 corresponds to bit k of the register 42 on the second die 4. Some alternative embodiments may have a more complex mapping between the registers. Each bit of the register 42 provides a respective output 44₀-44ₙ. Each output 44₀-44ₙ is coupled to a first input of a respective AND gate 46₀-46ₙ. Each of the AND gates 46 is arranged to receive a same synchronization signal as a second input. The synchronization signal is the synchronization signal received from input pad 40 and provided as the respective second inputs via a link or connection 48.

Each AND gate provides a respective output 50₀-50ₙ. Each of the respective outputs 50₀-50ₙ is provided to respective task circuitry 52₀-52ₙ. The task circuitry 52₀-52ₙ of the second die also has a one-to-one correspondence with the task circuitry of the first die 2. Accordingly, task circuitry 34ₙ₋₁ associated with task n−1 on the first die 2 corresponds to the circuitry 52ₙ₋₁ for performing task n−1 on the second die 4. However, some alternative embodiments of the invention may provide a more complex mapping between the task circuitry on the two dies.

In some embodiments of the present invention, the configuration registers 28 and 42 are controlled by the software running on the host CPU 6 in the first die 2. The register 42 in the second die 4 is programmed by the host CPU 6. In particular, the host CPU 6 is arranged to write data into the register 42. This occurs by the host CPU accessing the register 42 on the second die, using the respective buses on each die and the inter-die link 12. It should be appreciated that the software which controls the synchronization can be provided on either of the two dies. In some embodiments of the present invention, the synchronization control may be split across the two dies. For example, the host CPU on one die may control some tasks and the host CPU on the other die may control other tasks.

In one embodiment, the size of the registers will depend on the number of inter-die tasks which need to be synchronized. For example, if 10 tasks need to be synchronized, then each register will comprise 10 bits. It is of course possible to have registers which are programmable and accordingly, some of the bits may be unused. The registers may support any suitable number of tasks. Typically, the number of tasks may be between 2 and 50. However, this is by way of example only and some embodiments may support more than 50 tasks. The registers may have, in some embodiments of the invention, two or more bits associated with a given task.

The operation of the circuitry shown in FIG. 1 will now be described. In the following example, it is assumed that task 0 and task n−1 on the first die 2 need to be synchronized with the respective tasks on the second die 4. The host CPU sends a WRITE signal to the second die 4 via the path defined by connection 14, the interconnect bus 8, connection 16, the inter-die link 12, connection 18, interconnect bus 10 and connection 26. The WRITE signal writes a “1” into the bit for task 0 and into the bit for task n−1, in the register 42. As far as the host CPU 6 is concerned, although the register 42 on the second die 4 is on a different die to the host CPU 6, the host CPU 6 nevertheless considers the register 42 as address space which can be addressed by the host CPU 6. If the host CPU 6 needs to verify that the required bits have been written into the register 42 of the second die 4, the host CPU 6 may read the respective bits of the registers. However, this read action may be omitted in some embodiments.

The host CPU 6 then writes via the path comprising connection 14, interconnect bus 8 and connection 24 a “1” to the corresponding bits for task 0 and task n−1 of the register 28 of the first die 2. When this occurs, a “1” is then provided on the output 32₀ and 32ₙ₋₁. This causes the circuitry 34₀ for task 0 and the circuitry 34ₙ₋₁ for task n−1 to be initiated and also causes the OR gate 30 to provide a “1” output. This “1” output is passed from the output pad 38 to the input pad 40 and is then input to each of the AND gates. Those AND gates which already have a “1” as an input from the register bits which are set to one will provide a “1” output. In this example, those AND gates associated with task 0 and n−1 will provide the “1” output. Those AND gates which have a “1” output cause the circuitry 52ₙ₋₁ and 52₀ corresponding to tasks 0 and n−1 to be initiated.

As the signal circuitry is quite simple, the corresponding task circuitry is initiated on the second die at substantially the same time as on the first die or only with a relatively small time difference (due to gate delay). In some alternative embodiments, a delay may be provided for example in the form of two inverters on the first die to provide some compensation for the time taken for the synchronization signal to be propagated through the OR and AND gates. In practice this delay through the gates may be quite small and may be ignored in some cases. Alternatively or additionally, delay circuitry may be provided on the first die to compensate for the delay caused by the signal passing through the two pads.

In some of the described embodiments, the synchronization signal has been described as being in the form of “1” or so-called high signal. It is of course possible to have a synchronization signal in a form of a “0” or so-called low signal. Likewise, the bits have been described as being set to “1” in the registers in order to initiate the synchronization task. It is of course possible in alternative embodiments of the present invention to set a bit to “0” in the registers in order to initiate the respective tasks. The synchronization signal may be more complex in some embodiments requiring two or more parallel bits and/or two or more serial bits. The synchronization signal may be encoded with other data in alternative embodiments.

The register in the first die 2, that is the die that has the host CPU 6, is referred to as the tasks selection configuration register. A bit may be provided in each register for each task which requires synchronization in the two dies. One or more of these tasks can be executed at the same time.

In one embodiment, a given bit of this register 28 in the first die 2 is set only after the equivalent bit in the register 42 in the second die 4 has been set. However, in some alternative embodiments, the two bits may be set more or less at the same time or the bits of the register 28 on the first die may be set first. This may require in some embodiments that one or other of the registers is first cleared (for example the bit value is “0”) before the respective bit is set, (for example to “1”).

The register on the second die 4 may be referred to as a tasks mask selection configuration register. This register is configured to route the synchronization signal which is driven by the first die to the selected task circuitry.

It should be appreciated that in some embodiments, the number of inter-die pins can be minimized. In one embodiment, one pad is used on each die for the synchronization signal. This may, for some embodiments, provide a low cost implementation. It should be appreciated that in some alternative embodiments, more than one pad may be provided on each die for the connection. In another embodiment, the pads on the two dies may be shared with other circuitry or functions. The connection 52 may be a dedicated connection for the synchronization signal or may be shared, for example with the inter-die link. This may for example require some multiplexing circuitry.

Some embodiments may have no predefined order for the task synchronization. For example, the software on the host CPU may want to perform the task 3 followed by task 1 or indeed any other order. Some embodiments mean that the order of the tasks synchronization can be controlled in dependence on one or more events and/or the context. For example, the host CPU may decide to follow a certain order for the synchronization of a number of tasks depending on a given event/context or multiple events. By way of example only, the event or context may comprise external or internal interrupts or the like.

Some embodiments may be arranged such that there is no fixed delay between the synchronization of each task. This means that task synchronization which is dependent on irregular or not predictable events can be accommodated.

Some embodiments can be performed by a relatively simple software routine running on the host CPU.

Some embodiments may have relatively small timing uncertainty. In particular, the timing uncertainty between the synchronization signal seen by the two tasks on the two different dies may be relatively small, for example of the order of +/−20 ns. This may be achieved in some embodiments by the simplicity of the arrangement.

In some embodiments a single logic gate, for example an OR gate is used to generate the synchronization signal. Additionally or alternatively a single logic gate, for example an AND gate, is used to generate a control signal to initiate the task circuitry on the second die. The AND gate may be considered to be a control circuit for a respective task circuit. Of course alternative logic gates may be used in alternative embodiments. Other types of circuit arrangement may be used in some embodiments.

Some embodiments may maximize efficiency in that a relatively large number of tasks can be served using a unique instance of the same synchronization module. Thus it may be possible for the same synchronization signal to be used for more than one task if a different task requires synchronization at the same time. Alternatively, a single task can be synchronized at a time.

It should be appreciated that the controller is configured to write a “0” to the respective registers when the controller considers the tasks to have been performed. This may be after a given time period or may be responsive to signal or the like being detected by the controller.

In one embodiment, each entry of the register is arranged to be associated with allocated one of the tasks. In an alternative embodiment, the entries of the register can be programmed to be associated with different ones of the tasks.

In one embodiment, separate task circuitry is provided for each entry in the register. In some alternative embodiments, one or more of the task circuitry may be associated with a plurality of said entries.

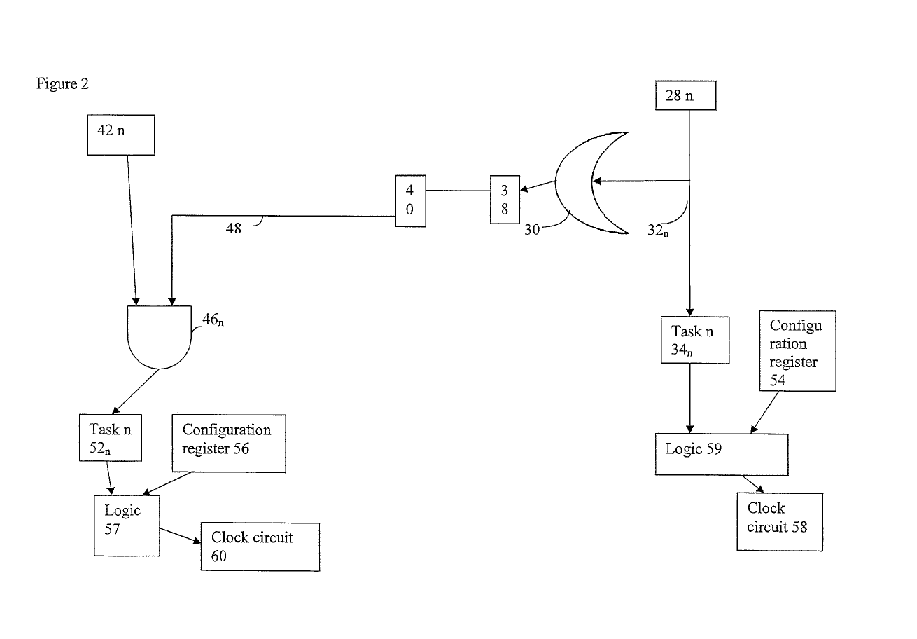

Reference is made to FIG. 2 which shows an example of one task which is synchronized in each of the two dies 2 and 4. In particular, the arrangement of FIG. 2 allows for the drift, compared to a third clock source (not shown), of two clocks generated locally on each die by the same instance of a clock generator. The arrangement of FIG. 2 allows the correction to be applied at the same time to both clock generators on each die. Thus circuitry provided in both dies allows the CPU to measure the drift and to apply the correction to both clock generators. Thus FIG. 2 shows a schematic illustration of a synchronization of the clock generators on the two dies is shown. This task is task n. Bit n of the register 42 on the second die 4 is set, that is has a “1” written into the location of the register associated with task n. This causes one of the inputs for the AND gate 46ₙ to go high (“1”).

Bit n of the register 28 of the first die 2 is likewise set. The writing of the “1” into the register 28 for bit associated with task n causes the synchronization signal to be output by the OR gate 30. This synchronization signal is input to the second input of the AND gate 46ₙ which causes the output of AND gate 46ₙ to go high.

On the second die, the output of the task circuitry 52ₙ is input to logic 57 which also receives the output of a configuration register 56. Likewise on the first die, the output of the task circuitry 34ₙ is input to logic 59 which also receives the output of a configuration register 56. Accordingly, the circuitry 34ₙ and 52ₙ associated with task n are respectively activated on the first die and the second die. In each case, the task circuitry 34ₙ and 52ₙ respectively provide a high output to the respective logic 57 and 59. This causes clock correction information from the respective configuration register 54 and 56 which is also applied to the logic 57 and 59 to be received by respective clock generation circuitry 58 and 60. The correction can then be applied to the respective clock generators of the of the two dies. In this way the two clocks on the two dies are brought back into synchronization.

In the absence of the activation signal from the task circuitry, no clock correction is applied to the clock circuitry.

It should be appreciated that FIG. 2 is by way of example only and the task circuitry may be configured in some alternative embodiments to directly perform the task or to cause the task to be performed.

The registers described above may be replaced by any other suitable memory or data storage.

It should be appreciated that the task circuitry and/or the signal circuitry may take the form of hardware, software or a combination thereof.

In one embodiment, the configuration registers may for example be part of the task circuitry. Additionally or alternatively, the task circuitry may be part of the circuitry which actually performs the task.

It should be appreciated that the task which is synchronized and shown in FIG. 2 is by way of example only. Alternative embodiments may be used to additionally or alternatively synchronize any other suitable task.

Some embodiments described have various connections. It should be appreciated that these connections may be direct or indirect. The connections may be provided by wired connection or the like or in alternative embodiments via a suitable coupling arrangement.

Some embodiments may be used with any two or more different die.

By way of example only, by allowing more than one die within a single package, decoupling of analog blocks from the digital blocks may be achieved. For example, the analog circuitry can be provided on one die and the digital circuitry can be provided on a different die. In this way, the analog die may have its required voltage and/or transistor gate oxide thickness whilst the digital part of the die can use a different voltage and/or transistor gate oxide thickness. It should be appreciated that in some embodiments, the digital die may predominantly contain digital circuitry and a relatively small amount of analog circuitry and/or the analog die may predominantly contain analog circuitry and a relative small amount of digital circuitry.

Alternatively or additionally, each die may be designed to provide a particular function which may require various different mixes of analog and digital circuitry in the implementation of that particular function. In some embodiments, this may mean that the same die or same design for a die may be used in different packages. By introducing this modularity, design time may be reduced.

In the following, a single package comprising two or more dies will be referred to as a system in package.

By way of example only, one system in package may comprise: a 32 nanometer die containing high speed CPUs (central processing units), one or more DDR3 controllers and other elements; and a 55 nanometer die containing analog PHYs (physical layer devices). As the analog circuitry is contained on a different die to that containing the digital circuitry, the 32 nanometer die is able to maximize the benefits from the reduction in size.

Some system in packages may be used for a set top box. For example, one die may comprise a set top box application die and another die a media processing engine. Alternatively one package could comprise an RF (radio frequency) die and a TV tuner die. Alternatively, a wireless networking PHY layer die may be incorporated in the same package as an RF die. Alternative embodiments may be used in a wide variety of different contexts. The following is a non exhaustive list of where some embodiments of the invention may be used: mobile phone chips; automotive products; telecoms products; wireless products; gaming application chips; personal computer chips; and memory chips.

Some embodiments may be used where there are two or more dies in a package. Embodiments may alternatively or additionally be used where it is advantageous for at least one of the dies to be certified, validated or tested independently for conformance to some standard. Embodiments may alternatively or additionally be used where one of the dies contains special-purpose logic to drive specific wireless, optical or electrical interfaces so that the other die(s) can be manufactured independently and not incur any cost associated with the special purpose logic. Embodiments may alternatively or additionally be used where one of the dies contains information (for example encryption information) which is to be withheld from the designers/manufacturers of the other dies. Embodiments may alternatively or additionally be used where one of the die contains high-density RAM or ROM and it is preferable to separate this from standard high speed logic for reasons of fabrication yield and/or product flexibility.

The above give some examples of different system in packages. However, it should be appreciated that alternative embodiments may be used for any system in package comprising two or more dies.

Whilst this detailed description has set forth some embodiments, the appended claims cover other embodiments of the present invention which differ from the described embodiments according to various modifications and improvements. Other applications and configurations may be apparent to the person skilled in the art.

What is claimed is:

1. A die comprising:
a controller configured to select at least one task to be performed on said die;
signal circuitry configured in response to the selection of said at least one task to provide a signal to be sent to a second die for initiating performance of a task on said second die which is corresponding to said selected at least one task; and
task circuitry configured to cause said selected at least one task to be performed on said die.

2. The die as claimed in claim 1, comprising;
a register comprising a plurality of entries, each entry corresponding to a task which is to be time coordinated with a corresponding task on said second die, said controller configured to set at least one entry of said register and to cause at least one corresponding entry to be set in a register on the second die.

3. The die as claimed in claim 2, wherein said signal circuitry is configured, in response to said at least one entry being set in said register to provide said signal to be sent to said second die.

4. The die as claimed in claim 2, wherein each entry of said register comprises a bit.

5. The die as claimed in claim 4, wherein said controller is configured to set an entry by setting said bit to a logic value.

6. The die as claimed in claim 2, wherein said controller is configured to set a plurality of entries at the same time.

7. The die as claimed in claim 2, wherein said signal circuitry is configured to be connected to each entry of said register and is responsive to the setting of any one or more entries to generate said signal as a synchronization signal.

8. The die as claimed in claim 2, wherein said signal circuitry and said task circuitry are configured to respond to said setting of said entry at substantially a same time.

9. The die as claimed in claim 2, wherein said controller is configured to cause said at least one corresponding entry in the register on the second die to be set before the at least one entry of said register on the first die is set.

10. A die comprising:
an input configured to receive a task selecting signal output from another die, said task selecting signal configured to select at least one task to be performed on said die;
an input configured to receive a task initiating signal output from said another die; and
task circuitry configured in response to said at least one task being selected and receipt of said task initiating signal to cause said at least one task to be performed.

11. The die as claimed in claim 10, comprising:
a register comprising a plurality of entries, each entry corresponding to a task which is to be time coordinated with a task on said another die, said task selecting signal configured to set at least one entry of said register, said task circuitry being configured in response to said at least one entry being set and the receipt of the task initiating signal to cause said at least one task corresponding to said entry to be performed.

12. The die as claimed in claim 11, comprising control circuitry for said task circuitry, said control circuitry having an input to receive said task initiating signal and a respective entry of said register, said control circuitry being configured to generate a control signal, when said synchronization signal has been received and said respective entry has been set, to cause said task circuitry to perform said task.

13. The die as claimed in claim 10, wherein said task circuitry comprises a plurality of task circuitry, each task circuitry being associated with one of said tasks.

14. The die as claimed in claim 13, wherein said each task circuitry is configured to receive the value of an associated entry for said task in a or said register

15. A package comprising a first die and a second die, comprising:
on said first die:
a controller configured to select at least one task to be performed on said first die and at least one corresponding task to be performed on said second die;
first signal circuitry configured in response to the selection of said at least one task to provide a first signal to be sent off said first die for application to said second die for initiating performance of said at least one corresponding task on said second die; and
first task circuitry configured to cause said selected at least one task to be performed on said first die in response to said selection; and
on said second die:
second signal circuitry configured in response to the selection of said at least one corresponding task to provide a second signal for initiating performance of said at least one corresponding task; and
second task circuitry configured to cause said selected at least one corresponding task to be performed on said first die in response to said second signal.

16. The package as in claim 15, wherein said at least one corresponding task to be performed on said second die comprises at least one corresponding task that is to be time coordinated for performance on said second with respect to the selected at least one task to be performed on said first die.

17. The package as in claim 15,
wherein said first die further comprises a first register comprising a plurality of entries, each entry corresponding to one task to be performed on said first die;
wherein said second die further comprises a second register comprising a plurality of entries, each entry corresponding to one corresponding task to be performed on said second die; and
said controller configured to set at least one entry of said first register and to further set at least one corresponding entry to be set in said second register.

18. The package of claim 17, wherein the first signal circuitry on said first die comprises a logic circuit configured to generate said first signal in response to a logic state of said first register entries.

19. The package of claim 17, wherein the second signal circuitry on said second die comprises a logic circuit configured to logically combine the first signal received from the first die with a logic state of each of said second register entries to generate a plurality of control signals for application to said second task circuitry.

20. The package of claim 17, wherein said controller is configured to set at least one corresponding entry in said second register before setting at least one entry of said first register.
